(19) United States
(12) Patent Application Publication
(10) Pub. No.: US 2014/0017613 A1
(43) Pub. Date: Jan. 16, 2014

(54) HOLDING APPARATUS, PROCESSING APPARATUS, LITHOGRAPHY APPARATUS, AND METHOD FOR MANUFACTURING ARTICLE

(71) Applicant: Canon Kabushiki Kaisha, Tokyo (JP)

(72) Inventor: Yuji Maehara, Saitama-shi (JP)

(21) Appl. No.: 13/938,413

(22) Filed: Jul. 10, 2013

(30) Foreign Application Priority Data
Jul. 11, 2012 (JP) 2012-155514

(51) Int. Cl. H01J 37/20

(52) U.S. Cl. CPC H01J 37/20
USPC 430/296; 269/20; 250/453.11

(57) ABSTRACT

A holding apparatus includes a base provided with a protrusion for supporting a substrate, and holds the substrate via liquid with which a gap between the substrate supported by the protrusion and the base is filled. The holding apparatus includes a heat storage member arranged on the base to be covered with the liquid. The heat storage member includes a latent heat storage material, and a heat conduction material containing the latent heat storage material to conduct heat to the latent heat storage material.

### BACKGROUND OF THE INVENTION

1. Field of the Invention

The present invention relates to a holding apparatus for holding a substrate.

2. Description of the Related Art

In an extreme ultraviolet radiation (EUV) exposure apparatus or an electron beam exposure (drawing) apparatus which has been developed as a next-generation semiconductor exposure apparatus at present, a substrate is exposed in a vacuum. In a vacuum, heat is not transferred by convection, so that heat tends to be stored in an object. For this reason, in the above-described exposure apparatuses, measures for heat (cooling of an object) are one of important development elements.

In cooling a substrate as an object to be exposed, there is a method for accelerating heat transfer from the substrate to a substrate holding unit (simply referred to as holding unit) by enclosing gas between the substrate and the holding unit. Further acceleration of heat transfer is demanded to improve resolution and overlay accuracy. There has been known a substrate holding apparatus (simply referred to as holding apparatus) for holding the substrate by a holding unit such that liquid is enclosed between the substrate and the holding unit (refer to International Publication No. WO 2009/011574). The holding apparatus holds the substrate by the holding unit by taking an advantage that the layer of the liquid becomes negative in pressure with respect to a vacuum atmosphere.

It is desirable for the holding unit to increase its heat capacity to reduce a change in temperature. However, it is not desirable to increase the volume (in size) of the holding unit. For that reason, there has been known a holding apparatus using a latent heat storage material which changes in phase (refer to Japanese Unexamined Patent Application Publication No. 2009-545157). The holding apparatus uses a heat storage structure combining a high heat conduction material with the latent heat storage material to increase the amount of heat transfer from the substrate to the latent heat storage material.

Japanese Unexamined Patent Application Publication No. 2009-545157 discusses a method for clamping a substrate for supplying the latent heat storage material (a material which changes in phase) as fluid between a layer of the substrate holding unit on which a bar (a protrusion) is provided and the substrate. However, this method requires to increase the number of the bars to ensure the transfer of heat to the latent heat storage material, so that it is described that it may incur a risk of losing the flatness of the substrate (refer also to Japanese Unexamined Patent Application Publication No. 2009-545157, paragraph number 0047).

### SUMMARY OF THE INVENTION

The present invention is directed to, for example, a holding apparatus advantageous in providing compatibility between transfer of heat from a substrate to the apparatus and flatness of the substrate.

According to an aspect of the present invention, a holding apparatus which includes a base provided with a protrusion for supporting a substrate, and holds the substrate via liquid with which a gap between the substrate supported by the protrusion and the base is filled includes a heat storage member arranged on the base to be covered with the liquid, wherein the heat storage member includes a latent heat storage material, and a heat conduction material containing the latent heat storage material to conduct heat to the latent heat storage material.

Further features of the present invention will become apparent from the following description of exemplary embodiments with reference to the attached drawings.

### BRIEF DESCRIPTION OF THE DRAWINGS

FIGS. 1A and 1B are examples illustrating a configuration of a substrate holding apparatus according to an exemplary embodiment.

FIG. 2 is a schematic diagram illustrating a change in volume of a heat storage structure (a heat storage member) and movement of an interface of liquid.

FIG. 3 illustrates an example of a configuration of the heat storage structure.

FIG. 4 illustrates another example of a configuration of the heat storage structure.

FIG. 5 is a schematic diagram of a drawing apparatus according to the exemplary embodiment.

### DESCRIPTION OF THE EMBODIMENTS

Various exemplary embodiments, features, and aspects of the invention will be described in detail below with reference to the drawings. In principle, the same reference numerals are used for the same components throughout the drawings, and thus the descriptions thereof are not repeated.

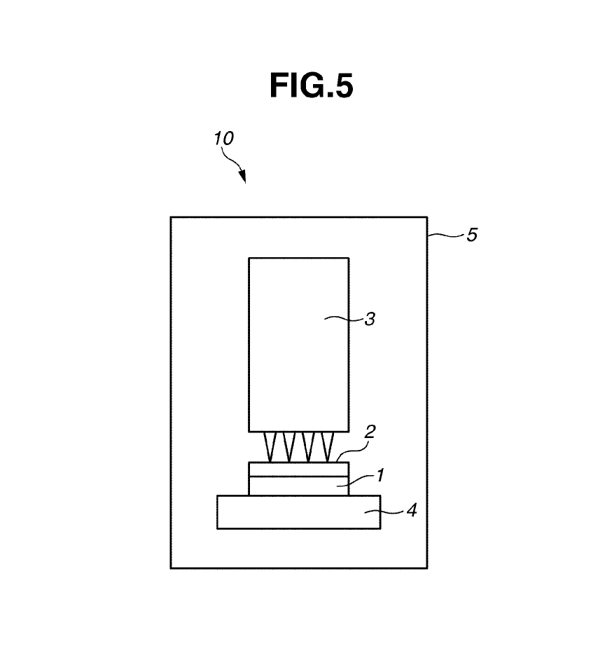

An example is described in which a substrate holding apparatus according to the present invention is applied to a drawing apparatus for performing drawing on a substrate with a charged particle beam, but not limited to the example and can be widely applied to various types of apparatuses. FIG. 5 is a schematic diagram of a drawing apparatus according to a first exemplary embodiment. Herein, the drawing apparatus which uses an electron beam as a charged particle beam is described as an example, however, the drawing apparatus may use other charged particle beams such as an ion beam. A drawing apparatus 10 includes a vacuum chamber 5 and an electro-optical system 3 and a stage 4 which are stored in the vacuum chamber 5 and is the one that performs drawing on a substrate with an electron beam in a vacuum. The stage 4 is movably configured to position a substrate 2 with respect to the electro-optical system 3 and includes a substrate holding apparatus 1 (simply referred to as a holding apparatus) for holding the substrate 2.

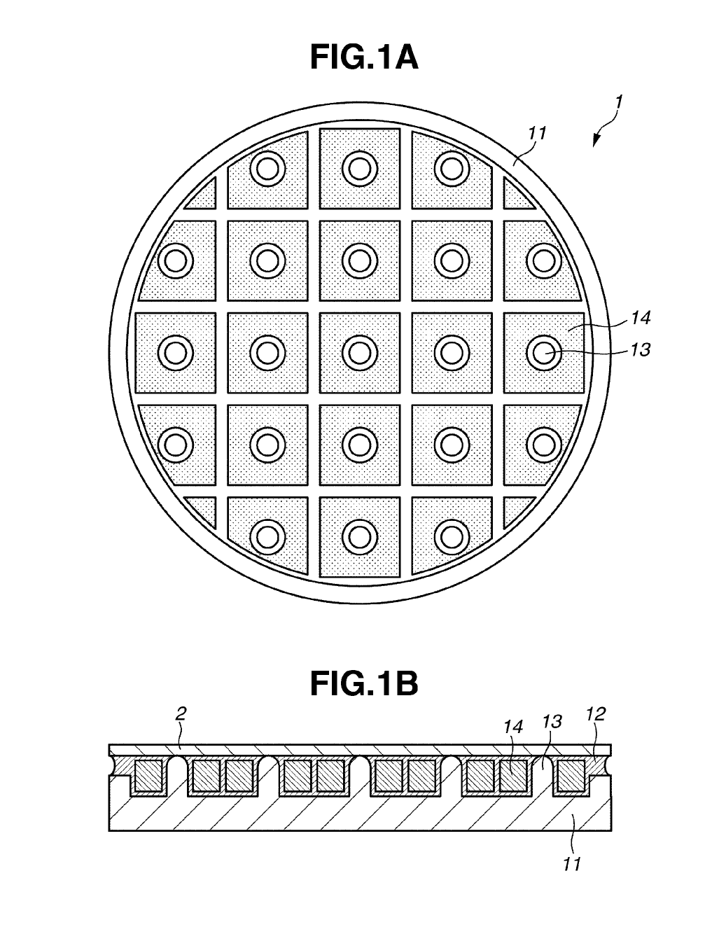

FIGS. 1A and 1B are a schematic diagram illustrating a configuration of the substrate holding apparatus 1 according to the first exemplary embodiment. FIG. 1A is a top view and FIG. 1B is a cross section of the substrate holding apparatus 1. The holding apparatus 1 includes a base 11 (a holding unit) provided with a protrusion 13 (a supporting unit). A gap between a substrate 2 supported by the protrusion 13 and the base 11 is supplied and filled with liquid 12. The liquid 12 may be selected in consideration of wettability (lyophilic) and heat conductivity of the substrate 2 and the base 11 and the influence thereof on an operating environment.

If the substrate holding apparatus 1 is used in a semiconductor manufacturing apparatus, water is preferably used as the fluid 12 to avoid the contamination of a semiconductor wafer. If the substrate holding apparatus 1 is used for other applications, it is allowable to use various greases or organic solvents (lower in heat conductivity than water), or low-melting metal or alloy (referred to as liquid metal, higher in heat conductivity than water).

Since surface tension (capillary pressure) toward the inside of the liquid 12 acts on the illustrated liquid surface, the substrate 2 is pressed against the base 11 by pressure (differential pressure) corresponding to a difference between the ambient pressure of the liquid 12 and the pressure of the liquid 12. The substrate 2 is held by base 11 so as not to be displaced sideways due to friction force occurring between the substrate 2 and the base 11 by the differential pressure. The liquid 12 contributes not only to the generation of force holding the substrate 2, but to the reduction of heat distortion of the substrate 2 by conducting heat applied to the substrate 2 due to drawing to the base 11 by its heat conductivity.

A heat storage structure 14 (also referred to as a heat storage member) includes a heat conduction material and a latent heat storage material. The heat storage structure 14 is arranged so as to avoid the protrusion 13 (a hole through which the protrusion 13 passes is formed) and to be covered with the liquid 12 in an area on the base 11 corresponding to the gap between the substrate 2 and the base 11. In FIGS. 1A and 1B, a plurality of separated heat storage structures 14 is arranged owing to necessity described below, however, if there is no necessity, an un-separated integrated (one) heat storage structure may be used. The heat transferred from the substrate 2 to the liquid 12 is absorbed in the latent heat storage material in the heat storage structures 14. A phase change of the latent heat storage material reduces a change in temperature of the heat storage structures 14, and thus a change in temperature of the substrate 2 can be reduced.

The heat storage structure 14 has such a structure that a heat conduction material includes (encloses) a latent heat storage material therein. A contact area can be ensured enough at least between a top surface of the heat storage structure 14 and the liquid 12, so that there is no need for increasing the number of the protrusions 13 to ensure the transfer of heat to the heat storage structure 14. Therefore, the present exemplary embodiment can provide the holding apparatus which is suitable to provide compatibility between the transfer of heat from the substrate to the holding unit and flatness of the substrate. Further, the structure according to the present exemplary embodiment is excellent in heat capacity of the holding unit because of using the latent heat storage material and thus suitable to stabilize temperature of the substrate.

If a single heat storage structure substantially covering the top surface of the base 11 is provided, the heat storage structure absorbing heat is expanded, so that it is desirable that an external dimension of the heat storage structure in a state where heat is not absorbed is made smaller in advance than an inside diameter of the holding unit in consideration of the expansion. Such a configuration allows reducing the deformation of the holding unit due to the expansion of the heat storage structure which absorbs heat.

As described above, if the integrated (single) heat storage structure is provided, there is no heat storage structure at an outer circumference of the gap between the holding unit and the substrate in a state where the heat storage structure does not absorb heat. This may cause a state where non-uniformity in temperature of the substrate is unallowable (for example, thermal deformation at the outer circumference of the substrate is unallowable). The following describes structure suitable for such a case.

In FIG. 1B, a plurality of separated heat storage structures 14 is arranged so as to avoid the protrusion 13 and to be covered with the liquid 12 in an area on the base 11 corresponding to the gap between the substrate 2 and the base 11. The base 11 includes a plurality of the protrusions 13. An individual heat storage structure 14 has a hole through which at least one of the plurality of the protrusions 13 (one in FIG. 1B) passes.

The heat storage structure 14 may be a complex containing a latent heat storage material including at least one of calcium chloride hydrate, sodium sulfate hydrate, and paraffin, and a heat conduction material which includes at least one of metal, ceramics, a carbon fiber, and resin and includes (encloses) the latent heat storage material therein. The latent heat storage material is a material that absorbs heat to change in phase from solid to liquid and is characterized in that temperature thereof does not change during the phase change and the amount of heat absorption per unit volume is large. The latent heat storage material and the heat conduction material are not limited to the above-described materials, and may be materials described below, for example, in a second and a third exemplary embodiment.

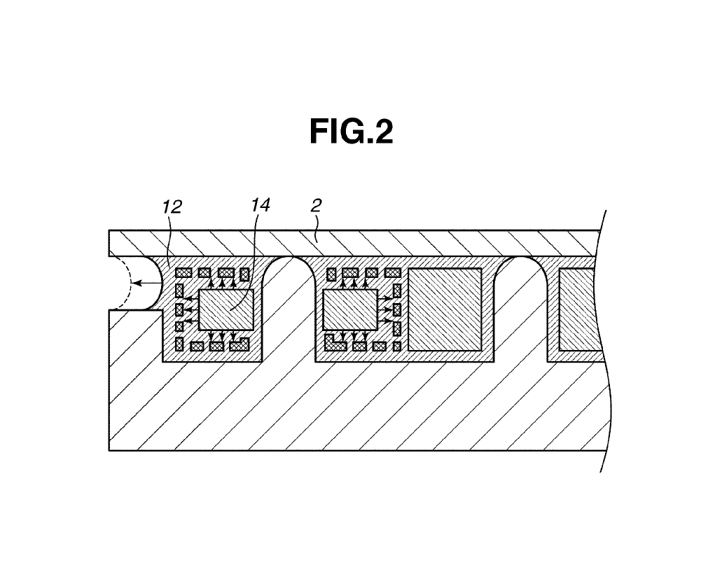

FIG. 2 is a schematic diagram illustrating a change in volume of the heat storage structure and the movement of an interface of the liquid. Heat generated on the substrate 2 by drawing using electron beams is moved to the heat storage structure 14 via the liquid 12. The movement of heat to the heat storage structure 14 causes a change of phase in the latent heat storage material included in the heat storage structure 14. The latent heat storage material is expanded by the phase change (the volume thereof is increased) to increase the volume of the heat storage structure 14 as indicated by a broken line. Along with that, the interface of the liquid 12 (a gas-liquid interface) also changes as indicated by a broken line.

The individual heat storage structure 14 arranged with a small interval in consideration of expansion is smaller in representative dimension and in an increase of the volume (amount of expansion) at the time of absorbing heat than the integrated heat storage structure. Thus, this configuration allows decreasing a variation in an entire outside dimension of the plurality of the heat storage structures 14 (variation in a difference between the outside dimension of the base 11 and the entire outside dimension of the plurality of the heat storage structures 14). For this reason, the configuration is suitable for maintaining uniformity of temperature of the substrate 2, and thus suitable to reduce the thermal deformation of outer circumference of the substrate 2, for example. In FIG. 1A, the individual heat storage structure 14 is rectangular in outer shape, however, the outer shape thereof is not limited to a rectangular shape. The outer shape thereof may be triangle or hexagonal, provided that the shape is good enough to allow the individual heat storage structure 14 to be densely arranged on the base 11.

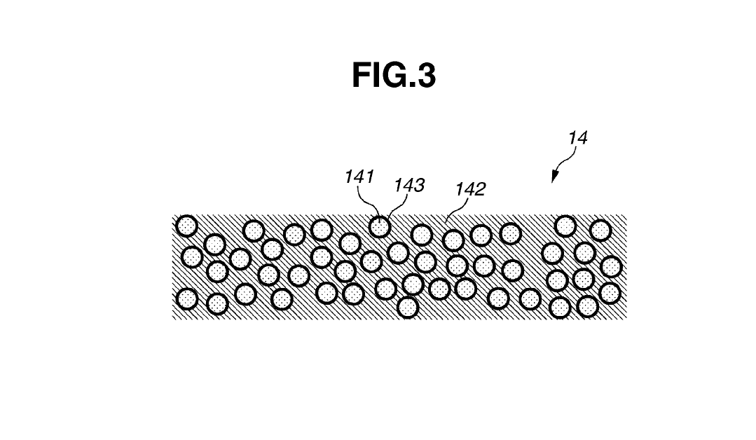

A second exemplary embodiment relates to an example of a configuration of the heat storage structure 14 in FIG. 1. If the latent heat storage material in the heat storage structure 14 is low in heat conductivity, the uniformity of temperature distribution is lowered. This may impair stability and uniformity of temperature of the substrate 2 to cause a change in dimension or a local deformation of the substrate 2. The configuration of the heat storage structure 14 in consideration of the above point is described below with reference to FIG. 3.

In FIG. 3, the heat storage structure 14 is formed from a latent heat storage material 141 and a heat conduction material 142 which includes the latent heat storage material 141 therein. The latent heat storage material 141 is a material that absorbs heat at a room temperature of 10° C. to 40° C. to change in phase from solid to liquid and is characterized in that a change in temperature is smaller than other materials because absorbed heat is used for the phase change. It is desirable that the latent heat storage material 141 is high in heat conductivity to increase the uniformity of temperature distribution. It is also desirable that the latent heat storage material 141 is high in amount of heat absorption per unit volume.

The heat conduction material 142 has a function of fixing the position of the latent heat storage material 141 by encircling the latent heat storage material 141, sealing the latent heat storage material 141 to prevent the latent heat storage material 141 from melting into the liquid 12, and conducting heat from the liquid 12 to the latent heat storage material 141. Therefore, the heat conduction material 142 needs to be formed of a material of which melting point, softening temperature, or molding temperature is higher than the melting point of the latent heat storage material 141.

As for the latent heat storage material 141, it is desirable to use a material adapting to conditions that a material has a melting point in the vicinity of a target temperature (about 23° C., for example) of the substrate 2 in the vacuum chamber 5 of the drawing apparatus 10 and is high in heat conductivity. For example, gallium or alloy in which at least one of metals selected from indium, tin, or zinc is added to gallium may be used.

The latent heat storage material 141 may be a powdery latent heat storage material. The surface of the latent heat storage material 141 may be coated with a material (a coating material 143) which has a melting point higher than the molding temperature of the heat conduction material 142 and is high in heat conductivity. The heat conduction material 142 and the coating material 143 may be at least one material selected from metal, ceramic, and resin. However, a material for the heat conduction material 142 is not limited to the exemplified materials.

The heat storage structure 14 can be produced by molding a raw material (in which a binder such as resin is kneaded if required) for the heat conduction material 142 into which the latent heat storage material 141 coated with the coating material 143 is mixed. The configuration of such a heat storage structure has a benefit in that the heat storage structure 14 can be simply produced by molding. Powder molding such as pressure molding, injection molding, extrusion molding, casting, and tape-casting can be used for a method for molding the heat storage structure. However, the molding method is not limited to the exemplified methods.

According to the present exemplary embodiment, the selection of the latent heat storage material allows providing the heat storage structure suitable from a viewpoint of the uniformity of temperature distribution, for example, and enables providing the substrate holding apparatus which is excellent in stability and uniformity of temperature of the substrate and suitable for reducing a dimensional change and a local deformation of the substrate.

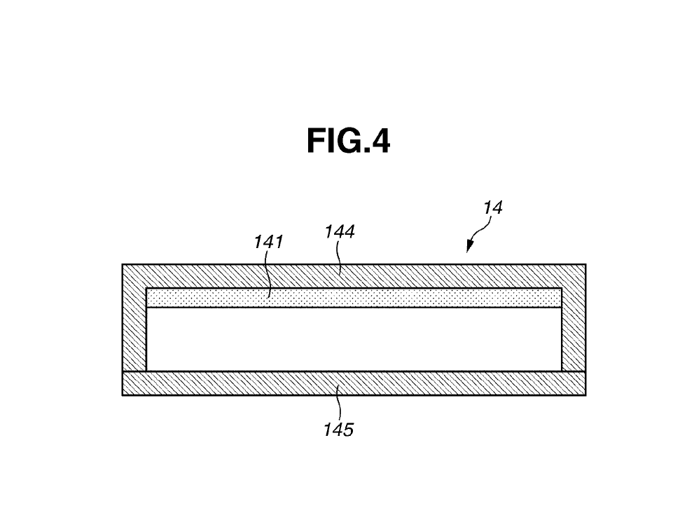

A third exemplary embodiment relates to an example of a configuration of the heat storage structure 14 in FIG. 1. The configuration of the heat storage structure according to the present exemplary embodiment is described below with reference to FIG. 4. In FIG. 4, the heat storage structure 14 is formed from a latent heat storage material 141, a container 144 for the latent heat storage material 141, and a sealing member 145. The latent heat storage material 141 is arranged in contact with at least one surface inside a hermetically-sealed container formed of the container 144 and the sealing member 145.

Thus, in the individual heat storage structure 14, the configuration in which the integrated latent heat storage material is arranged in close contact with the inner surface of the hermetically-sealed container including the latent heat storage material is advantageous in efficiency of heat transfer from a back side of the substrate 2 to the latent heat storage material 141. The latent heat storage material 141 can include, for example, gallium or alloy in which at least one of the metals selected from indium, tin, or zinc is added to gallium in consideration for the similar conditions as in the case of the second exemplary embodiment. The container 144 and the sealing member 145 can include at least one material selected from metal, ceramic, and resin, as is the case with the heat conduction material 142 in the second exemplary embodiment.

The heat storage structure 14 can be produced such that the latent heat storage material 141 is deposited on the container 144 and then the container 144 is bonded to the sealing member 145, for example. The latent heat storage material 141 can be deposited using a deposition method selected from vapor deposition, sputtering, and coating. However, the deposition method is not limited to the exemplified methods. The container 144 can be bonded to the sealing member 145 using a bonding method selected from adhesion, welding, and room temperature bonding. However, the bonding method is not limited to the exemplified methods.

According to the present exemplary embodiment, the selection of the latent heat storage material allows providing the heat storage structure suitable from a viewpoint of the uniformity of temperature distribution, for example, and enables providing the substrate holding apparatus which is excellent in stability and uniformity of temperature of the substrate and suitable for reducing a dimensional change and a local deformation of the substrate.

A method for manufacturing an article according to a fourth exemplary embodiment of the present invention is suitable to manufacture an article such as a micro device like a semiconductor and an element with microstructure, for example. The manufacturing method includes a process for forming a latent image pattern on a photosensitive material of the substrate coated with the photosensitive material using the drawing apparatus (a process for performing drawing on the substrate) and a process for developing the substrate on which the latent image pattern is formed in the drawing process. The manufacturing method may further include other known processes (oxidation, deposition, vapor deposition, doping, flattening, etching, resist stripping, dicing, bonding, packaging, and so on). The method for manufacturing an article according to the present exemplary embodiment is excellent in at least one of performance, quality, productivity, and production cost of the article when compared to conventional methods.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

The application of the substrate holding apparatus according to the exemplary embodiments is not limited to that of a drawing apparatus for performing drawing on a substrate with a charged particle beam in a vacuum, for example, but the substrate holding apparatus is applicable to other various apparatuses. Further, the substrate holding apparatus may be applicable to a lithography apparatus for forming a pattern on a substrate with a beam instead of a charged particle beam in a vacuum or a processing apparatus for subjecting a substrate to processing except exposure in a vacuum, for example. Furthermore, the substrate holding apparatus according to the exemplary embodiments is also applicable to a processing apparatus for subjecting a substrate to processing at an air or gas pressure (at atmospheric pressure, for example) except vacuum.

FIG. 1 illustrates a configuration in which the plurality of the heat storage structures 14 which avoids the protrusion 13 and is separated each other is arranged on the base 11 covered with the liquid 12. The configuration is directed to a decrease of a variation in an entire outside dimension of the plurality of the heat storage structures 14 (variation in a difference between the outside dimension of the base 11 and the entire outside dimension of the plurality of the heat storage structures 14). As long as the purpose is achieved, the plurality of the heat storage structures 14 does not necessarily need to be completely separated from each other. Accordingly, the incompletely separated heat storage structure also falls within “the plurality of the heat storage structures”.

For example, at least a part of the plurality of the heat storage structures 14 may be coupled with each other by a coupling member to facilitate handling of the heat storage structures 14. In this case, the coupling member includes a material and have a shape and a dimension which do not substantially affect a variation in an entire outside dimension of the plurality of the heat storage structures and in dimension and shape of the gap due to expansion and contraction of the plurality of the heat storage structures arranged on the base. The coupling member may be a member including a flexible thin string, for example. The coupling member may be molded along with the heat conduction material 142.

This application claims the benefit of Japanese Patent Application No. 2012-155514 filed Jul. 11, 2012, which is hereby incorporated by reference herein in its entirety.

What is claimed is:

1. A holding apparatus which includes a base provided with a protrusion for supporting a substrate, and holds the substrate via liquid with which a gap between the substrate supported by the protrusion and the base is filled, the holding apparatus comprising:
a heat storage member arranged on the base to be covered with the liquid,
wherein the heat storage member includes a latent heat storage material, and a heat conduction material containing the latent heat storage material to conduct heat to the latent heat storage material.

2. The holding apparatus according to claim 1, wherein a plurality of the heat storage members are arranged with a gap therebetween.

3. The holding apparatus according to claim 1, wherein the base includes a plurality of the protrusions, and
the heat storage member is provided with a hole through which at least one of the plurality of the protrusions passes.

4. The holding apparatus according to claim 1, wherein the latent heat storage material includes metal.

5. The holding apparatus according to claim 4, wherein the metal includes any of gallium and alloy in which at least one of indium, tin, and zinc is added to gallium.

6. The holding apparatus according to claim 1, wherein the latent heat storage material is covered with a substance of which melting point is higher than a molding temperature of the heat conduction material.

7. The holding apparatus according to claim 1, wherein the heat conduction material forms a closed container containing the latent heat storage material, and the latent heat storage material is in contact with an inner surface of the closed container.

8. The holding apparatus according to claim 1, wherein the liquid is water.

9. A processing apparatus for processing a substrate, the processing apparatus comprising:
a holding apparatus, defined in claim 1, for holding the substrate.

10. A lithography apparatus for forming a pattern on a substrate, the lithography apparatus comprising:
a holding apparatus, defined in claim 1, for holding the substrate.

11. The lithography apparatus according to claim 10, wherein the pattern is formed with a charged particle beam.

12. A method for manufacturing an article, the method comprising:
forming a pattern on a substrate using a lithography apparatus;
developing the substrate on which the pattern has been formed; and
processing the developed substrate to manufacture the article,
wherein the lithography apparatus includes a holding apparatus which includes a base provided with a protrusion for supporting the substrate and holds the substrate via liquid with which a gap between the substrate supported by the protrusion and the base is filled, the holding apparatus including
a heat storage member arranged on the base to be covered with the liquid,
wherein the heat storage member includes a latent heat storage material and a heat conduction material containing the latent heat storage material to conduct heat to the latent heat storage material.
